(19) United States
(12) Patent Application Publication
(10) Pub. No.: US 2021/0341558 A1
(43) Pub. Date: Nov. 4, 2021

(54) CORRECTION OF MISMATCHES IN MAGNETIC RESONANCE MEASUREMENTS

(71) Applicant: Siemens Healthcare GmbH, Erlangen (DE)

(72) Inventors: Dominik Paul, Bubenreuth (DE); Mario Zeller, Erlangen (DE)

(21) Appl. No.: 17/226,899

(22) Filed: Apr. 9, 2021

(30) Foreign Application Priority Data
Apr. 29, 2020 (DE) 102020205382.0

(51) Int. Cl. G01R 33/565; G01R 33/56; G01R 33/561

(52) U.S. Cl. CPC G01R 33/56554; G01R 33/5616; G01R 33/5608

(57) ABSTRACT

A computer-implemented method is provided for generating correction information for correcting mismatches in magnetic resonance measurements. Magnetic resonance data is received, wherein a generation of the magnetic resonance data includes several partial measurements by a magnetic resonance device. During each partial measurement, a k-space region is sampled at least partially, wherein the k-space regions of different partial measurements differ at least partially in their extent in the readout direction, and wherein the extent in the readout direction depends on prephasing gradients and readout gradients generated by the magnetic resonance device during the partial measurements. A trained function of a machine learning algorithm is applied to the received magnetic resonance data, wherein correction information for correcting a mismatch of the prephasing gradients and readout gradients is generated and output.

The present patent document claims the benefit of German Patent Application No. 10 2020 205 382.0, filed Apr. 29, 2020, which is hereby incorporated by reference in its entirety.

### TECHNICAL FIELD

The present disclosure relates to a method for generating correction information for correcting mismatches in magnetic resonance measurements. The disclosure further relates to a computer-implemented method for providing a trained function for providing correction information for correcting mismatches in magnetic resonance measurements. Finally, the disclosure relates to a magnetic resonance device.

### BACKGROUND

Correction parameters for nuclear magnetic resonance (NMR) or magnetic resonance imaging (MRI) measurements may be set in advance in order to optimize the results. For example, the resonance frequency is determined in order to maximize the resonance signal. In addition, an adjustment of the homogenization flows, known as shimming, may be carried out.

Furthermore, correction factors may be used for gradient strengths or moments. These correction factors compensate a mismatch of the gradient field for given flows.

Moreover, gradient-related correction factors may be used which are sequence-specific.

One sequence in which the sequence-specific correction factors may be advantageous is what is known as the RESOLVE sequence, described in Porter and Heidemann, “High Resolution Diffusion-Weighted Imaging Using Readout-Segmented Echo-Planar Imaging, Parallel Imaging and a Two-Dimensional Navigator-Based Reacquisition”, MRM, 62:468-475, 2009. The RESOLVE sequence is readout-segmented and uses a sinusoidal readout gradient and is thus a segmented echo-planar imaging (EPI) sequence. In contrast to conventional multi-shot EPI sequences, the segmentation here takes place in the readout direction. A mismatch between the dephasing gradient in the readout direction and the sinusoidal readout gradient results in ring-shaped or “football-shaped” artifacts, referred to in the following as “ringing artifacts.”

To avoid the ringing artifacts, a correction factor is multiplied either by the moment of the dephasing gradient or by the sinusoidal readout moment, for example, by the duration or the gradient strength.

This correction factor may be obtained by varying several parameters, in particular, however also by varying the correction factor itself. Further possible parameters are the type of the magnetic resonance device, the echo spacing, and the gradient orientation. Different magnetic resonance device types have different gradient systems and radio frequency (RF) coils in the interior, which influence the signal acquisition.

These parameters are varied specifically, and an image is recorded for each parameter set. These images may contain 128×128 or more data points. A large number of images is therefore acquired, which are then evaluated with the naked eye or automatically by generating values which characterize the image quality. The image with the fewest artifacts determines the best correction factor. For each combination of parameters, such as echo spacing, gradient orientation, and all other relevant parameters, the most suitable correction factor is found. The correction factor may lie between 0.995 and 1.025.

The adjustment of the correction factor is therefore very time-consuming and is therefore carried out only once when the first magnetic resonance apparatus of a particular series is installed.

Furthermore, a mismatch of the gradients in the phase encoding direction may occur, for example, in turbo spin echo (TSE) sequences. There, the k-space may be segmented in the phase encoding direction. Mismatches accumulate to produce a phase error. The problem described may furthermore also occur in the slice selection direction.

Even if the artifacts are compensated at the start of the service life of an MR scanner, this may change on account of the deterioration of the material. The artifacts then change and may grow in the course of the service life of the scanner.

Artifacts may occur whenever two gradients which influence the magnetization are applied in the same direction. If one or more of the gradients are applied multiple times in one excitation cycle, the artifacts may become even stronger.

### SUMMARY AND DESCRIPTION

It is therefore an object of the disclosure to compensate a mismatch between the gradients during magnetic resonance measurements, wherein the adjustment is to be flexible and wherein the time spent by the patient in the MR scanner should ideally not be extended.

This object is achieved by a computer-implemented method for generating correction information for correcting mismatches during magnetic resonance measurements, a computer-implemented method for providing a trained function for providing correction information for correcting mismatches in magnetic resonance measurements, and a magnetic resonance device.

The scope of the present disclosure is defined solely by the appended claims and is not affected to any degree by the statements within this summary. The present embodiments may obviate one or more of the drawbacks or limitations in the related art.

According to one aspect, the disclosure correspondingly relates to a computer-implemented method for generating correction information for correcting mismatches in magnetic resonance measurements. Magnetic resonance data is received, wherein a generation of the magnetic resonance data includes several partial measurements by a magnetic resonance device, wherein during each partial measurement a k-space region is sampled at least partially. The k-space regions of different partial measurements differ at least partially in their extent (e.g., location, size, or scale) in the readout direction. Further, the extent in the readout direction depends on prephasing gradients and readout gradients generated by the magnetic resonance device during the partial measurements. A trained function of a machine learning algorithm is applied to the received and, if applicable, processed magnetic resonance data, wherein correction information for correcting a mismatch of the prephasing gradients and readout gradients is generated and output.

According to a further aspect, the disclosure relates to a computer-implemented method for providing a trained function for providing correction information for correcting mismatches in magnetic resonance measurements. To this end, input training data which may include processed magnetic resonance data is received, which has been generated based on several partial measurements by a magnetic resonance device. In each partial measurement, a k-space region is sampled at least partially, wherein the k-space regions of different partial measurements differ at least partially in their extent in the readout direction. The extent in the readout direction depends on prephasing gradients and readout gradients, which the magnetic resonance device generates during the partial measurements. Output training data is provided, wherein the output training data includes correction information for correcting a mismatch of the prephasing gradients and readout gradients. The function is trained based on the input training data and the output training data. The trained function is provided.

According to a further aspect, the disclosure relates to a computer program product with executable program code, which is embodied to carry out the method when executed on a computer.

According to a further aspect, the disclosure relates to a non-volatile, computer-readable storage medium with executable program code, which is embodied to carry out the method when executed on a computer.

According to a further aspect, the disclosure relates to a magnetic resonance device with a magnetic resonance data acquisition scanner which carries out partial measurements, wherein the magnetic resonance data acquisition scanner samples a k-space region at least partially during each partial measurement. The k-space regions of different partial measurements differ at least partially in their extent in the readout direction, wherein the extent in the readout direction depends on prephasing gradients and readout gradients generated by the magnetic resonance data acquisition scanner during the partial measurements. The magnetic resonance device further includes a memory, which is embodied to store magnetic resonance data generated by the magnetic resonance data acquisition scanner. The magnetic resonance device further includes a computer, which is embodied to read out the magnetic resonance data from the memory and carry out the method for generating correction information.

The disclosure enables a reverse determination of the correction factor. The number of items of magnetic resonance data required is thus significantly reduced. It is no longer necessary to perform actual measurements for different correction factors. In this way, the measurements may be carried out without great effort, as a result of which the measurement time may be kept to a minimum. Moreover, the correction factor may be determined on a patient-specific or measurement-specific basis. If only one mismatch has to be compensated over longer periods, the determination of the correction information may be carried out after predefined periods, for example, every six months.

In addition, the correction information itself may be used even if the setting options provided by the magnetic resonance device do not cover the recording parameters determined.

To obtain the correction information at a later time, this is determined after the MRI measurement. A mismatch of the gradients causes a displacement and/or scaling and/or phase modulation of the k-space, which may subsequently be corrected.

With regard to signal acquisition, certain features will be explained in more detail below.

A set of parameters may be a set of values used to carry out a scan. This may be the duration of an RF pulse, a delay, the RF frequency, the echo time, the repetition time, etc.

An excitation pulse is used to excite the magnetization. The flip angle of the excitation pulse normally lies in the range of 0° and 90°. In spin echo sequences and gradient echo sequences, the flip angle may be exactly 90°. Rapid gradient echo sequences may also have smaller flip angles. The excitation pulse is also used to define the length of the repetition time, which corresponds to the length of an excitation cycle. Each sampling sequence has at least one excitation pulse.

An excitation cycle may also be referred to as a partial measurement. In a partial measurement, a k-space region is sampled. A segmented measurement includes several partial measurements. In a TSE measurement, for example, segmentation is performed in the phase encoding direction so that the k-space is sampled not all at once but in several acts.

In particular, a RESOLVE sequence may be used, which represents a segmented EPI sequence. This segmentation is achieved by a sinusoidal readout gradient, wherein only a small k-space region is covered in the readout direction, while the displacement between the segments takes place by a dephasing gradient.

According to a development of the method for generating correction information, the segmentation of the k-space resulting from the partial measurements takes place at least in the readout direction and may additionally take place in the phase encoding direction and/or slice selection direction.

In a further embodiment, the readout gradient is applied several times in a partial measurement. In particular, the readout gradient may be used to generate or during the generation of an echo train. Changing the sign of the readout gradient serves to generate a gradient echo train. Alternatively, the readout gradient may be applied several times with the same sign in the phase encoding direction before the echo signals are read out. This may be the case if an EPI-TSE sequence is used.

During each partial measurement, an echo train with several echo signals may be acquired. An echo train may include up to dozens of echo signals. There may be 40 to 50 echo signals, for example.

According to a development of the method for generating correction information, a magnetic resonance output image is generated based on the magnetic resonance data, wherein a mismatch of the prephasing gradients and readout gradients is corrected based on the correction information output by the trained function.

According to a development of the method for generating correction information, the magnetic resonance data is processed, wherein the processed magnetic resonance data includes at least one magnetic resonance image generated based on the magnetic resonance data. The trained function of the machine learning algorithm is applied to the processed magnetic resonance data.

According to a development of the method for generating correction information, the at least one magnetic resonance image is generated based on magnetic resonance data relating to a subset of the k-space.

According to a development of the method for generating correction information, the at least one magnetic resonance image is generated based on magnetic resonance data relating to a subset of the partial measurements.

According to a development of the method for generating correction information, the at least one magnetic resonance image is transformed. In particular, the at least one magnetic resonance image may be trimmed.

According to a development of the method for generating correction information, the correction information for correcting a mismatch of the prephasing gradients and readout gradients includes at least one correction factor, wherein the at least one correction factor describes a correction of a data set of a partial measurement in the k-space. The correction may include a rescaling, rotation, phase modulation, and/or displacement of the data set of the partial measurement in the k-space.

According to a development of the method, the magnetic resonance data, such as echo signals or magnetic resonance signals, is displaced in the k-space based on the correction factor in order to correct the mismatch of the gradients. This displacement may be carried out individually for each data point of a k-space region, even if only one correction factor is used. This takes place from a starting point at which the position is assumed to be correct, which is normally at the start of a line. The distance from the starting position may then be varied by multiplying the distance from the starting position in the predefined direction by the correction factor. Here, the k-space region is enlarged if the correction factor is greater than 1 or compressed if the correction factor is less than 1. The correction factor may be used to compensate a mismatch after the measurement. This results in displaced magnetic resonance data.

In a further embodiment, the displaced magnetic resonance data is rastered in the k-space. The echo signals are referenced to k-space points. If the sampling scheme and/or the multiplication by the correction factor gives a difference between the acquisition position and the required position, a re-ordering may be performed. This is referred to as gridding, because the k-space points of a grid are transferred into a Cartesian grid.

Irrespective of whether a radial, sinusoidal or a Cartesian sampling scheme is used, the k-space data points, in other words the echo signals, may be rastered with regard to the correction factor used.

Advantageously, all k-space regions are rastered with the same correction factor when an image is produced. This means that the mismatch is caused by reproducible deviations.

Moreover, the echo signals may be acquired overlapping one another in the k-space, particularly in the readout direction. Alternatively or in addition, the signals may also overlap one another in the phase encoding and/or in the slice selection direction. The echo signals may overlap one another in the directions in which the segmentation takes place. The k-space is covered even if the k-space regions are compressed. As a result, the signal-to-noise ratio is improved.

The correction factor to be used may lie in the range of 0.995 and 1.025. The overlapping may be selected such that the k-space is fully covered even with a correction factor of 0.995.

According to a development of the method for generating correction information, the correction factor determined may be applied in addition to a correction factor already applied to the gradient moments during the acquisition of the raw data set.

Following the acquisition of an echo train, at least one navigator echo signal may be acquired. A patient positioned in the scanner of a magnetic resonance device may move during the setting measurements, which take just a few seconds. The results may then be improved further by eliminating the movement artifacts. Furthermore, the readout gradient of the navigator echoes may also have a sinusoidal shape. The navigator echo signal serves to eliminate phase errors which occur as a result of pulsation or movement during the application of the diffusion encoding gradients. The image phase varies spatially between the individual recordings. This results in inconsistencies during composition and thus strong artifacts, which may be corrected based on the navigator echo signal.

According to a development of the method for generating correction information, a sphere phantom filled with doped water may be used as a sample for improving the determination of the correction factor. As a result, a constant signal is generated, and artifacts may then be identified easily.

According to a development of the method for generating correction information, the trained function of the machine learning algorithm is applied to data of the partial measurements in the k-space.

According to a development of the method for generating correction information, the readout gradients have a sinusoidal shape. This enables the k-space to be sampled in a segmented manner in the readout direction.

According to a development of the method for generating correction information, the k-space regions of the partial measurements cover the k-space fully in the phase encoding direction. The segmentation then takes place exclusively in the readout direction. Alternatively, the segmentation may also take place only in the phase encoding direction.

According to a development of the method, the k-space is acquired by Cartesian sampling. Here, k-space regions are sampled which are arranged in parallel in the k-space.

According to a development of the method for generating correction information, the trained function is based on an artificial neural network. The artificial neural network may be a convolutional neural network (CNN). In particular, it may be an artificial neural network for classification, such as a residual neural network (ResNet).

According to a development of the method for providing the trained function, the magnetic resonance data generated based on partial measurements is transformed by a multiplicity of predefined items of correction information, such as correction factors, in order to generate a multiplicity of transformed items of magnetic resonance data with associated correction information. The input training data includes the modified magnetic resonance data. The output training data includes the associated correction information for each modified magnetic resonance data set.

According to a development of the method for providing the trained function, the training of the function takes place in the image space. To this end, the segmented k-space lines may first be processed accordingly. The training of the function may take place both in the image space and in the k-space. Furthermore, a hybrid space may also be used, such as an x-k_{y} space, wherein coordinates in the image space as well as in the k-space may be used.

### BRIEF DESCRIPTION OF THE DRAWINGS

The above-described characteristics, features, and advantages of this disclosure, as well as the manner in which these are realized, will become clearer and more readily understandable in connection with the following description of the exemplary embodiments, which are explained in more detail in conjunction with the drawings, in which:

FIG. 1 depicts an example of a schematic representation of a magnetic resonance device.

FIG. 2 depicts an example of a sequence diagram of a RESOLVE sequence.

FIG. 3 depicts an example of a k-space acquisition scheme of a RESOLVE sequence.

FIG. 4 depicts exemplary phantom images, which have been generated with different correction factors.

FIG. 5 depicts an example of a flow diagram of a method for generating correction information for correcting mismatches in magnetic resonance measurements.

FIG. 6 depicts an example of a diagram to explain a method for generating correction information for correcting mismatches in magnetic resonance measurements.

FIG. 7 depicts an exemplary k-space line.

FIG. 8 depicts an example of two adjacent k-space lines.

FIG. 9 depicts an example of two compressed k-space lines.

FIG. 10 depicts an example of two extended k-space lines.

FIG. 11 depicts an example of a flow diagram of a method for providing a trained function for correcting mismatches in magnetic resonance measurements.

FIG. 12 depicts a schematic block diagram of a computer program product according to an embodiment.

FIG. 13 depicts a schematic block diagram of a non-volatile, computer-readable storage medium according to an embodiment.

### DETAILED DESCRIPTION

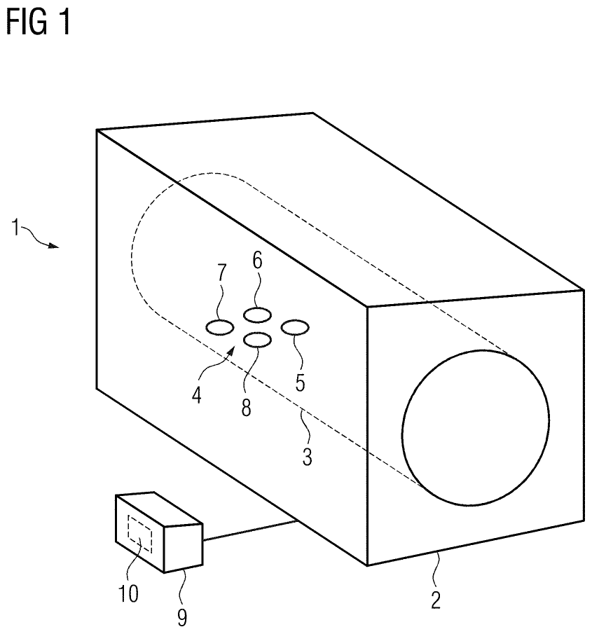

FIG. 1 depicts a magnetic resonance device 1 with a magnetic resonance data acquisition scanner 2. A transmit coil arrangement 3 is part of the magnetic resonance data acquisition scanner 2. The transmit coil arrangement 3 may include a single coil.

Furthermore, the magnetic resonance apparatus 1 has a receive coil arrangement 4. The receive coil arrangement 4 is a coil arrangement with individual coils 5, 6, 7 and 8. In order to be able to distinguish more easily between the coils 5, 6, 7, and 8, the transmit coil arrangement 3 is shown dashed.

A computer 9 controls the operation of the magnetic resonance device 1. The computer 9 serves as a control device and evaluation device, and may include microprocessors, FPGAs, integrated circuits, or the like. The nuclear magnetic resonance device 1 also has, as part of the computer 9 or independently therefrom, a non-volatile memory 10, in which the computer code for carrying out nuclear magnetic resonance measurements is stored.

The receive coil arrangement 4 serves to read out the measured signal, which may be an echo signal. The coils 5, 6, 7, and 8 of the receive coil arrangement 4 read out the measured signal simultaneously. An individual coil may also be used as a detection coil instead of the receive coil arrangement 4.

Further components of the nuclear magnetic resonance device 1, such as gradient coils and a patient bed, are not shown for the sake of clarity.

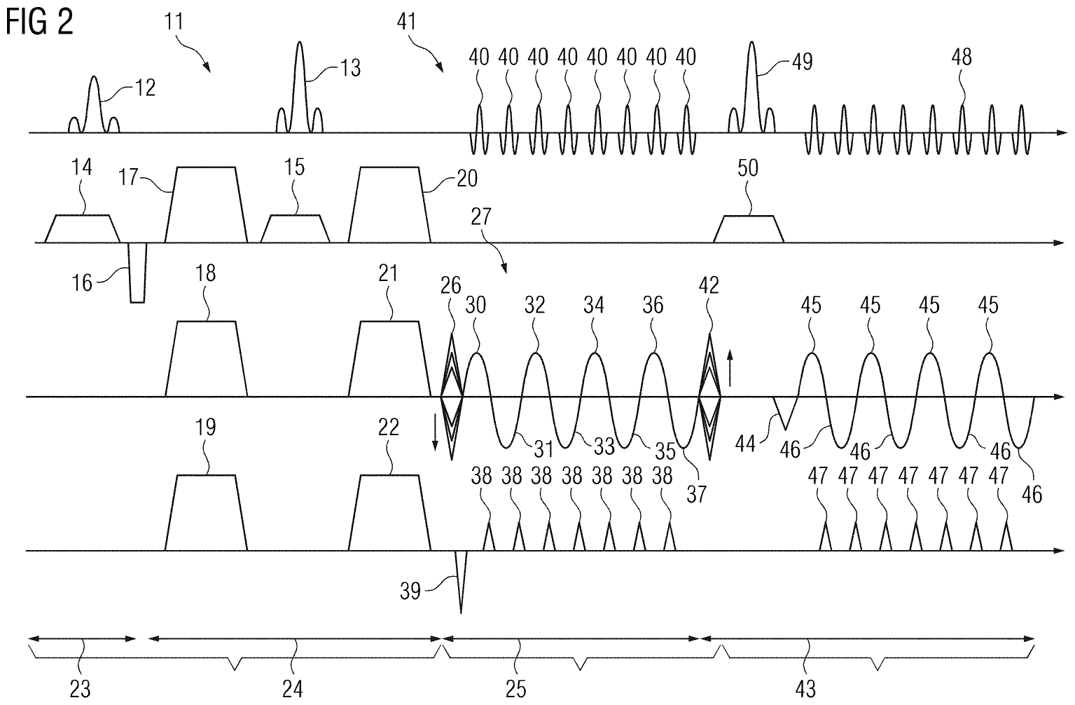

FIG. 2 depicts a sequence diagram 11 of a RESOLVE sequence, which is known for example from Porter and Heidemann, “High Resolution Diffusion-Weighted Imaging Using Readout-Segmented Echo-Planar Imaging, Parallel Imaging and a Two-Dimensional Navigator-Based Reacquisition”, MRM, 62:468-475, 2009.

A diffusion preparation section includes an excitation pulse 12 and a refocusing pulse 13. Slice selection gradients 14 and 15 are simultaneously provided in order to select a defined slice.

An additional slice rephasing gradient 16 may be used to compensate the dephasing portion of the slice selection gradient 14. Furthermore, diffusion encoding gradients 17, 18, and 19 may be used before the refocusing pulse 13 and corresponding gradients 20, 21, and 22 after the refocusing pulse 13.

The excitation pulse 12 and the selection gradient 14 and the slice rephasing gradient 16 are part of an excitation phase 23 of the RESOLVE sequence. The following development phase 24 lasts until the end of the diffusion gradients 20, 21, and 22.

The readout phase 25 begins thereafter. A dephasing gradient 26 with different gradient moments, through variation of its strength, brings the start of the readout in the readout direction to a desired position in the k-space.

A sinusoidal readout gradient 27 has a multiplicity of curves 30, 31, 32, 33, 34, 35, 36, and 37. Each of the curves 30, 31, 32, 33, 34, 35, 36, and 37 encodes a partial line in a readout direction in the k-space.

Phase encoding gradients 38 displace the encoding by one act in the phase encoding direction. The phase encoding gradients 38 are also referred to as blips or gradient blips.

An initial phase encoding gradient 39, like the dephasing gradient 26, sets the start of the readout in the phase encoding direction to a desired position in the k-space.

All echo signals 40 of a region or segment may be acquired in the readout phase 25. All echo signals of an excitation cycle generate an echo train 41. At the end of the readout phase, the encoding is reset to the starting point through the creation of a gradient 42 which has the same gradient moment as the dephasing gradient 26 but the opposite sign.

The readout phase 25 is followed by a navigator phase 43. The respective gradients 44, 45, 46, and 47 correspond to the analog gradients of the readout phase 25. The echo signals 48 are generated with a refocusing pulse 49 and a slice selection gradient 50.

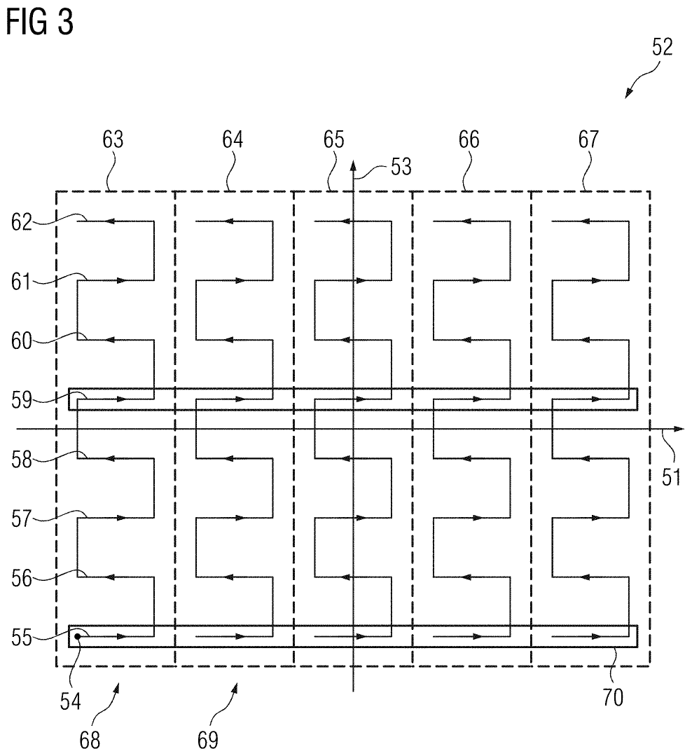

FIG. 3 depicts a k-space acquisition scheme, which corresponds to the sequence 11. An axis 51 designates the k(x) direction of the k-space 52 and an axis 53 designates the k(y) direction. The k(x) direction is also referred to as the readout direction and the k(y) direction as the phase encoding direction.

Following preparation of the signal, (e.g., by diffusion weighting), the gradients 26 and 39 set the encoding to the first starting point 54. This is, as discussed above, a possible starting point for the enlargement or compression of the partial line 55. The partial line 55 is acquired while the curve 30 is being applied, and the partial line 56 is applied simultaneously with the curve 31. The displacement of the phase encoding direction is achieved by one of the phase encoding gradients 38.

The additional partial lines 57, 58, 59, 60, 61, and 62 are generated in the same way. The partial lines 55 to 62 or echo signals 40 form an echo train 41.

The partial lines 55 to 62 cover a region 63 of the k-space 52 which is segmented in the k(x) direction.

The application of the sequence 11 using a dephasing gradient 26 with a different gradient moment enables the acquisition of the echo signals of one of the regions 64, 65, 66, or 67 of the k-space 52.

If an echo train 41 has all echo signals of a region 63 to 67 of the k-space 52, a number of excitation cycles is required which corresponds to the number of regions of the k-space 52.

If an echo train 41 has only a fraction of the echo signals of a k-space region, the excitation cycle is repeated more frequently. The k-space 52 is then divided into the readout direction and the phase encoding direction.

The trajectories 68 and 69 of two adjacent regions, (e.g., regions 63 and 64), have a gap for the sake of clarity. In reality, the echo signals of a k-space line cover the k-space 52 without gaps.

The images are reconstructed from the echo signals of all excitation cycles which have the same position as a k-space line in the phase encoding direction.

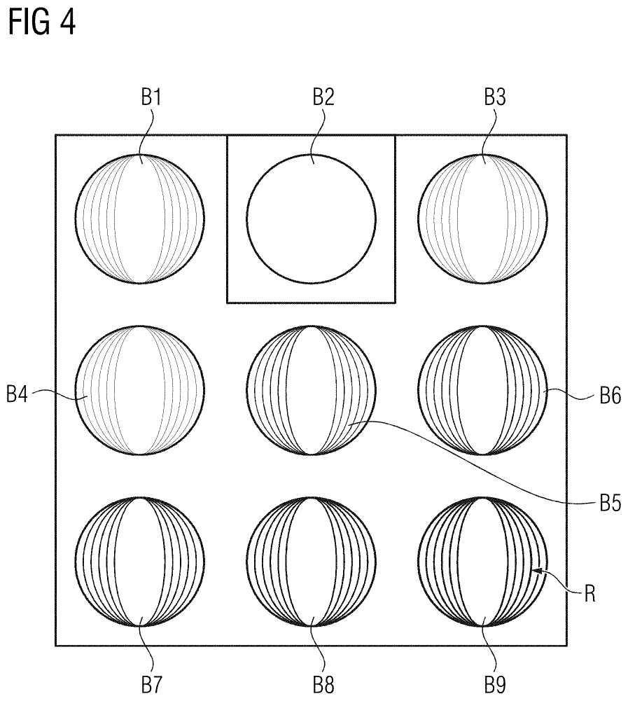

FIG. 4 depicts exemplary phantom images B1 to B9, which have been generated with different correction factors. As may be seen from FIG. 4, ringing artifacts R occur for most of the correction factors. For the optimum correction factor (according to phantom image B2), the ringing artifacts R have substantially disappeared.

FIG. 5 depicts a flow diagram of a method for generating correction information for correcting mismatches in magnetic resonance measurements.

In method act S11, magnetic resonance data is generated by a magnetic resonance device 1 with the RESOLVE sequence according to FIG. 2 by carrying out several partial measurements. In each partial measurement, one of the regions 63 to 67 is sampled. The regions 63 to 67 all overlap one another slightly on the left or right side. The extent (e.g., location, size, or scale) of the k-space region of each partial measurement depends on the prephasing gradient 26 and the readout gradient 27.

In method act S12, a trained function of a machine learning algorithm is applied to the received magnetic resonance data. Correction information for correcting a mismatch of the prephasing gradients 26 and readout gradients 27 is generated and output here. The trained function may be based on an artificial neural network, in particular a convolutional neural network.

Furthermore, provision may be made for a magnetic resonance output image to be generated based on the magnetic resonance data, wherein the correction information output by the trained function is used to correct a mismatch of the prephasing gradients 26 and readout gradients 27. Here, the magnetic resonance output image may be generated based on k-space data.

Furthermore, provision may be made for the magnetic resonance data to be k-space data, which is evaluated in order to generate a magnetic resonance image. The magnetic resonance image may be used as input data for the trained function. Alternatively, k-space data or certain subsets thereof may also be changed as input data for the trained function.

The correction information for correcting the mismatch of the prephasing gradients 26 and readout gradients 27 may include at least one correction factor. This describes a correction of a data set of a partial measurement in the k-space. The correction may be a rescaling, a rotation, a phase modulation, and/or a displacement of the data set of the partial measurement in the k-space. For example, all k-space point coordinates which correspond to the partial lines may be multiplied by the correction factor. If the readout gradient 27 is too strong, a correction factor of less than 1 would be applied to a gradient moment in order to obtain the correct gradient moment if it were prospectively multiplied. If the readout gradient 27 is stronger than it should be, the sampled k-space is accordingly wider than it should be. Then, assuming that the starting point has the right position, a retrospective multiplication of the k-space point coordinates corrects the data in the same manner as the prospective multiplication applied to the gradient moments.

The correction factors may be applied in the readout direction using a RESOLVE sequence. Correction factors greater than 1 extend the k-space lines in the readout direction, correction factors less than 1 compress them in the readout direction.

The displaced raw data sets may be rastered on k-rasters with Cartesian grids. Furthermore, the correspondingly processed magnetic resonance data of the k-space may be Fourier transformed in order to generate an output image.

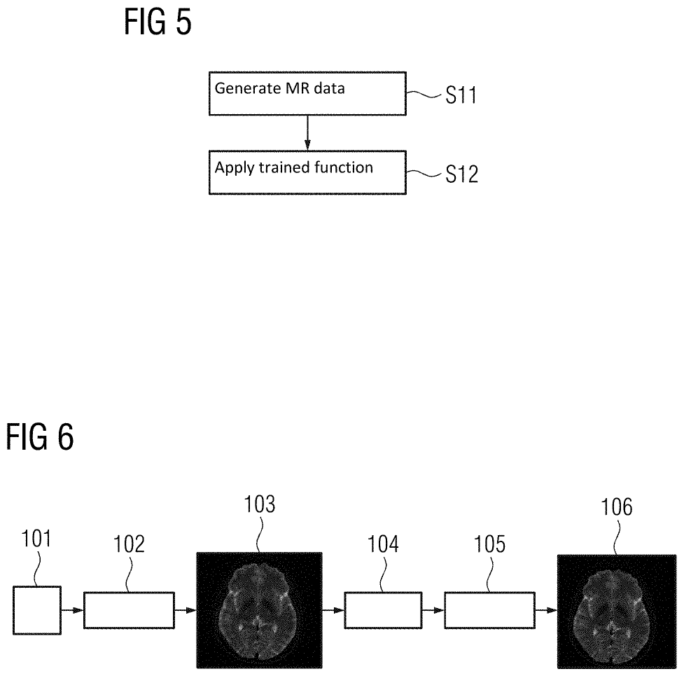

FIG. 6 depicts a block diagram to explain a method for generating correction information for correcting mismatches in magnetic resonance measurements. Here, magnetic resonance data 101 is provided. The MR data 101 is evaluated, 102, wherein the multiplication by an initially predefined correction factor and a Fourier transformation may be included. The evaluation may also be applied only to one part of the magnetic resonance data 101, such as a single slice, a subset of the acquired regions, or a subset in the k-space.

By the evaluation, a magnetic resonance image 103 is generated and provided to a trained function 104. This outputs an optimum correction factor so that an evaluation of the magnetic resonance data with the optimum correction factor is performed, 105. A corresponding magnetic resonance output image 106 is output. During generation of the magnetic resonance output image 106, the magnetic resonance data may be fully evaluated.

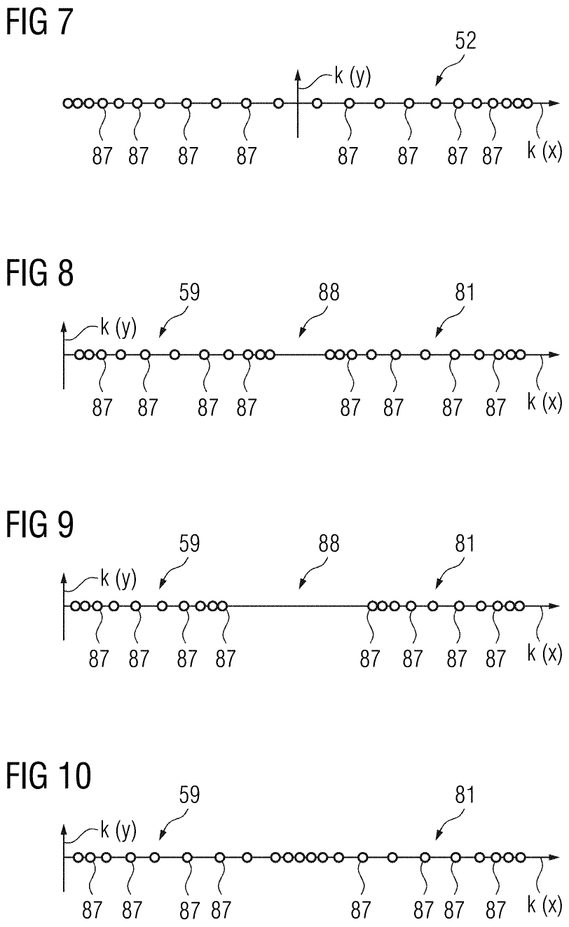

FIG. 7 depicts one of the partial lines 55 to 62. The sampling density varies, in other words the k-space points 87 have different spacings, so that the k-space points 87 are rastered to a Cartesian grid. The k-space points 87 of a partial line represent one of the measured echo signals 40.

FIG. 8 depicts two partial lines 59 and 81 of two adjacent regions 63 and 64 without application of a correction factor. The readout gradient 27 is weaker than assumed, so that there is a gap 88 between the regions 63 and 64. This gap is represented in an exaggerated manner in order to show the effects clearly.

FIG. 9 depicts the same partial lines 59 and 81 if a correction factor of less than 1 is applied. Then the gap 88 is greater than previously, which results in stronger ringing artifacts.

FIG. 10 depicts the partial lines 59 and 81 if a correction factor of greater than 1 and in particular the optimum correction factor is applied. The gap 88 has then disappeared and the k-space points are perfectly positioned.

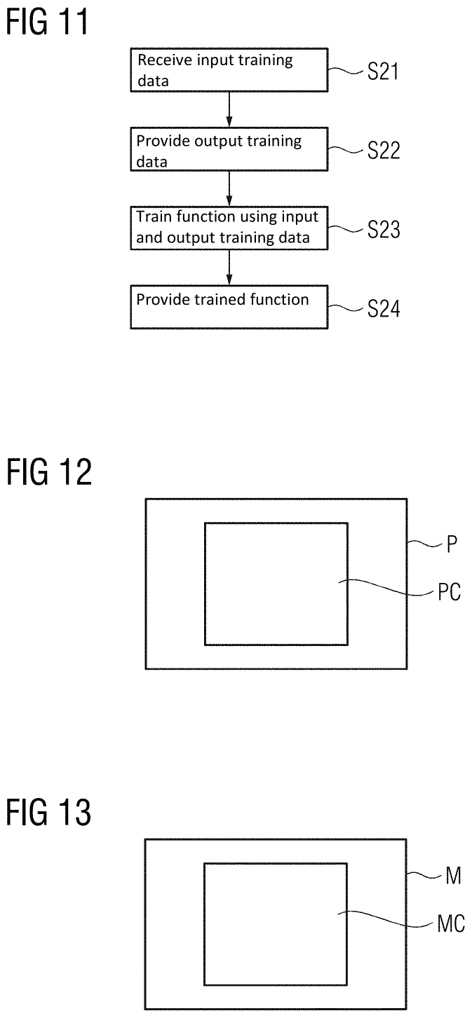

FIG. 11 depicts a flow diagram of a method for providing a trained function for generating correction information for correcting mismatches in magnetic resonance measurements.

In method act S21, input training data is received, which includes magnetic resonance data which has been generated based on several partial measurements by a magnetic resonance device 1. In each partial measurement, a k-space region is sampled, wherein the k-space regions of different partial measurements differ at least partially in their extent in the readout direction. Overall, the entire k-space is to be covered. The extent in the readout direction depends on prephasing gradients and readout gradients, which the magnetic resonance device 1 generates during the partial measurements.

In method act S22, output training data is provided, wherein the output training data includes correction information for correcting a mismatch of the prephasing gradients and readout gradients.

In method act S23, the function is trained based on the input training data and the output training data.

The trained function is provided in method act S24.

An exemplary architecture of a convolutional neural network, on which the trained function is based, is shown in the following Table 1.

TABLE 1

| Slice | Output format | Number of parameters |
|---|---|---|
| Conv2d | [64, 96, 96] | 9408 |
| BatchNorm2d | [64, 96, 96] | 128 |
| ReLU | [64, 96, 96] | 0 |
| MaxPool2d | [64, 48, 48] | 0 |
| Conv2d | [64, 48, 48] | 36864 |
| BatchNorm2d | [64, 48, 48] | 128 |
| ReLU | [64, 48, 48] | 0 |
| Conv2d | [64, 48, 48] | 36864 |
| BatchNorm2d | [64, 48, 48] | 128 |
| Conv2d | [64, 48, 48] | 36864 |
| BatchNorm2d | [64, 48, 48] | 128 |
| ReLU | [64, 48, 48] | 0 |
| Conv2d | [64, 48, 48] | 36864 |
| BatchNorm2d | [64, 48, 48] | 128 |
| Conv2d | [128, 24, 24] | 73728 |
| BatchNorm2d | [128, 24, 24] | 256 |
| ReLU | [128, 24, 24] | 0 |
| Conv2d | [128, 24, 24] | 147456 |
| BatchNorm2d | [128, 24, 24] | 256 |
| Conv2d | [128, 24, 24] | 8192 |
| BatchNorm2d | [128, 24, 24] | 256 |
| Conv2d | [128, 24, 24] | 147456 |
| BatchNorm2d | [128, 24, 24] | 256 |
| ReLU | [128, 24, 24] | 0 |
| Conv2d | [128, 24, 24] | 147456 |
| BatchNorm2d | [128, 24, 24] | 256 |
| Conv2d | [256, 12, 12] | 294912 |
| BatchNorm2d | [256, 12, 12] | 512 |
| ReLU | [256, 12, 12] | 0 |
| Conv2d | [256, 12, 12] | 589824 |
| BatchNorm2d | [256, 12, 12] | 512 |
| Conv2d | [256, 12, 12] | 32768 |
| BatchNorm2d | [256, 12, 12] | 512 |
| Conv2d | [256, 12, 12] | 589824 |
| BatchNorm2d | [256, 12, 12] | 512 |
| ReLU | [256, 12, 12] | 0 |
| Conv2d | [256, 12, 12] | 589824 |
| BatchNorm2d | [256, 12, 12] | 512 |
| Conv2d | [512, 6, 6] | 1179648 |
| BatchNorm2d | [512, 6, 6] | 2359296 |
| ReLU | [512, 6, 6] | 0 |
| Conv2d | [512, 6, 6] | 2359296 |
| BatchNorm2d | [512, 6, 6] | 1024 |
| Conv2d | [512, 6, 6] | 131072 |
| BatchNorm2d | [512, 6, 6] | 1024 |
| Conv2d | [512, 6, 6] | 2359296 |
| BatchNorm2d | [512, 6, 6] | 1024 |
| ReLU | [512, 6, 6] | 0 |
| Conv2d | [512, 6, 6] | 2359296 |
| BatchNorm2d | [512, 6, 6] | 1024 |
| AdaptiveAvgPool2d | [512, 1, 1] | 0 |
| AdaptiveMaxPool2d | [512, 1, 1] | 0 |
| Flatten | [1024] | 0 |
| BatchNorm1d | [1024] | 2048 |
| Dropout | [1024] | 0 |
| Linear | [512] | 524800 |
| ReLU | [512] | 0 |
| BatchNorm1d | [512] | 1024 |
| Dropout | [512] | 0 |
| Linear | [31] | 1026 |

The convolutional neural network shown is a ResNet18 architecture for image classification. In the final slice, a linear operation is performed which reduces the number of output variables to the number of possible correction factors. For example, 31 factors may be used in the region from 0.995 to 1.025. In an alternative variant, a regression takes place in the final act instead of a classification. This means that a continuous value in the range of 0.995 and 1.025 is output.

Furthermore, provision may be made to train an artificial network such as a ResNet18 network, which outputs whether the input image has artifacts or is free from artifacts. In the final slice of the artificial network, two potential results are thus possible.

The magnetic resonance data generated based on partial measurements may be transformed by a multiplicity of predefined items of correction information in order to generate a multiplicity of transformed items of magnetic resonance data with associated correction information. Here, the input training data may include the modified magnetic resonance data, and the output training data may include the associated correction information. In addition, a multiplication of the training data may take place by mirroring, rotation, scaling, compression or trimming. Because magnetic resonance measurements may acquire a multiplicity of parallel slices and may be recorded with a multiplicity of coil elements, a further multiplication of the training data may take place by a data set being divided into single-slice and single-channel images.

FIG. 12 depicts a schematic block diagram of a computer program product P with executable program code PC. The executable program code PC is embodied to carry out the method described above when executed on a computer.

FIG. 13 depicts a schematic block diagram of a non-volatile, computer-readable storage medium M with executable program code MC, embodied to carry out the method described above when executed on a computer.

It is to be understood that the elements and features recited in the appended claims may be combined in different ways to produce new claims that likewise fall within the scope of the present disclosure. Thus, whereas the dependent claims appended below depend from only a single independent or dependent claim, it is to be understood that these dependent claims may, alternatively, be made to depend in the alternative from any preceding or following claim, whether independent or dependent, and that such new combinations are to be understood as forming a part of the present specification.

Although the disclosure has been illustrated and described in detail by the exemplary embodiments, the disclosure is not restricted by the examples disclosed and other variations may be derived therefrom by a person skilled in the art without departing from the protective scope of the disclosure.

1. A computer-implemented method for generating correction information for correcting mismatches in magnetic resonance measurements, the method comprising:
receiving magnetic resonance data, wherein the magnetic resonance data comprises several partial measurements by a magnetic resonance device, wherein during each partial measurement a k-space region is sampled at least partially, wherein the k-space regions of different partial measurements differ at least partially in an extent in a readout direction, and wherein the extent in the readout direction of a respective partial measurement depends on prephasing gradients and readout gradients generated by the magnetic resonance device during the respective partial measurement of the different partial measurements; and
applying a trained function of a machine learning algorithm to the magnetic resonance data, wherein correction information for correcting a mismatch of the prephasing gradients and the readout gradients is generated and output.

2. The method of claim 1, wherein a magnetic resonance output image is generated based on the magnetic resonance data, and
wherein a mismatch of the prephasing gradients and the readout gradients is corrected based on the correction information output by the trained function.

3. The method of claim 2, wherein the magnetic resonance data is processed,
wherein the processed magnetic resonance data comprises at least one magnetic resonance image generated based on the magnetic resonance data, and
wherein the trained function of the machine learning algorithm is applied to the processed magnetic resonance data.

4. The method of claim 3, wherein the at least one magnetic resonance image is generated based on magnetic resonance data relating to a subset of the k-space.

5. The method of claim 4, wherein the at least one magnetic resonance image is further generated based on magnetic resonance data relating to a subset of the partial measurements.

6. The method of claim 1, wherein the magnetic resonance data is processed,
wherein the processed magnetic resonance data comprises at least one magnetic resonance image generated based on the magnetic resonance data, and
wherein the trained function of the machine learning algorithm is applied to the processed magnetic resonance data.

7. The method of claim 6, wherein the at least one magnetic resonance image is generated based on magnetic resonance data relating to a subset of the k-space.

8. The method of claim 6, wherein the at least one magnetic resonance image is generated based on magnetic resonance data relating to a subset of the partial measurements.

9. The method of claim 1, wherein the correction information for correcting a mismatch of the prephasing gradients and the readout gradients comprises at least one correction factor,
wherein the at least one correction factor describes a correction of a data set of a partial measurement in the k-space, and
wherein the correction comprises one or more of a rescaling, a rotation, a phase modulation, or a displacement of the data set of the partial measurement in the k-space.

10. The method of claim 1, wherein the trained function of the machine learning algorithm is applied to data of the partial measurements in the k-space.

11. The method of claim 1, wherein the readout gradients have a sinusoidal shape.

12. The method of claim 1, wherein the k-space regions of the partial measurements fully cover the k-space in a phase encoding direction.

13. The method of claim 1, wherein the trained function is based on an artificial neural network.

14. The method of claim 13, wherein the artificial neural network is a convolutional neural network.

15. A computer-implemented method for providing a trained function for generating correction information for correcting mismatches in magnetic resonance measurements, the method comprising:
receiving input training data, wherein the input training data comprises magnetic resonance data generated based on several partial measurements by a magnetic resonance device, wherein each partial measurement a k-space region has been sampled at least partially, wherein the k-space regions of different partial measurements differ at least partially in an extent in a readout direction, and wherein the extent of the readout direction of a respective partial measurement depends on prephasing gradients and readout gradients generated by the magnetic resonance device during the respective partial measurement of the different partial measurements;
providing output training data, wherein the output training data comprises correction information for correcting a mismatch of the prephasing gradients and the readout gradients;
training the function based on the input training data and the output training data; and
providing the trained function.

16. The method of claim 15, wherein the magnetic resonance data generated based on the partial measurements is transformed by a multiplicity of predefined items of correction information in order to generate a multiplicity of items of transformed magnetic resonance data with associated correction information,
wherein the input training data comprises the modified magnetic resonance data, and
wherein the output training data comprises the associated correction information.

17. A magnetic resonance device comprising:
a magnetic resonance data acquisition scanner configured to carry out partial measurements, wherein the magnetic resonance data acquisition scanner is configured to sample a k-space region at least partially during each partial measurement, wherein the k-space regions of different partial measurements differ at least partially in an extent in a readout direction, and wherein the extent in the readout direction of a respective partial measurement depends on prephasing gradients and readout gradients generated by the magnetic resonance data acquisition scanner during the respective partial measurement of the different partial measurements;
a memory configured to store the magnetic resonance data generated by the magnetic resonance data acquisition scanner; and
a computer configured to read out the magnetic resonance data from the memory and apply a trained function of a machine learning algorithm to the magnetic resonance data, wherein correction information for correcting a mismatch of the prephasing gradients and the readout gradients is generated and output.
